(19) United States
(12) Patent Application Publication
(10) Pub. No.: US 2015/0064809 A1
(43) Pub. Date: Mar. 5, 2015

(54) SUBSTRATE SUPPORT SYSTEM

(71) Applicant: Applied Materials, Inc., Santa Clara, CA (US)

(72) Inventor: Dmitry LUBOMIRSKY, Cupertino, CA (US)

(21) Appl. No.: 14/455,028

(22) Filed: Aug. 8, 2014

Related U.S. Application Data
(60) Provisional application No. 61/872,545, filed on Aug. 30, 2013.

(51) Int. Cl. H01L 21/66; H01L 21/687; H01L 21/68

(52) U.S. Cl. CPC H01L 22/20; H01L 21/68; H01L 21/68707
USPC 438/5; 414/749.1

(57) ABSTRACT

A method and apparatus for a substrate support system for a substrate process chamber, the chamber comprising a chamber body enclosing a processing region, a primary substrate support and a secondary substrate support at least partially disposed in the processing region, the secondary substrate support circumscribing the primary substrate support, wherein one or both of the primary substrate support and the secondary substrate support are movable relative to each other, and the primary substrate support is rotatable relative to the secondary substrate support.

### CROSS-REFERENCE TO RELATED APPLICATION

This application claims the benefit of U.S. Provisional Patent Application Ser. No. 61/872,545 (Attorney Docket No. 021062USAL), filed Aug. 30, 2013, which is hereby incorporated by reference in its entirety.

### BACKGROUND

1. Field

Embodiments of the disclosure generally relate to a substrate support system for a process chamber. More particularly, embodiments described herein relate to a substrate support system wherein non-uniformities measured on a substrate may be averaged (i.e., moved closer to a norm) by one or a combination of moving the substrate relative to a pedestal or moving the pedestal relative to the substrate using the substrate support system.

2. Description of the Related Art

Integrated circuits have evolved into complex devices that can include millions of components (e.g., transistors, capacitors, resistors, and the like) on a single chip. The evolution of chip designs continually requires faster circuitry and greater circuit density. The demands for greater circuit density necessitate a reduction in the dimensions of the integrated circuit components. The minimal dimensions of features of such devices are commonly referred to in the art as critical dimensions. The critical dimensions generally include the minimal widths of the features, such as lines, columns, openings, spaces between the lines, and device/film thickness and the like. As these critical dimensions shrink, accurate measurement and process control becomes more difficult.

Formation of these components is performed in a controlled environment, such as a process chamber, wherein a substrate is transferred for processing. The process chamber typically includes a pedestal that supports the substrate during the formation. The pedestal may be heated, cooled, function as an electrode, capable of rotation and/or vertical displacement and/or angular displacement, and combinations thereof. The heating, cooling, and/or electrical bias (collectively “substrate processing properties”) should be uniform across the face of the substrate in order to facilitate uniform conditions and thus uniform processing (e.g., deposition, etch, and other processes) across the substrate.

However, the pedestal may not perform reliably in order to deliver satisfactory substrate processing properties measured on the substrate. As one example, temperature of the pedestal may be non-uniform which results in non-uniform temperatures across the substrate. While the pedestal may include zones having individual temperature control means, the pedestal may not be capable of delivering thermal energy efficiently across the entire surface area of the substrate. Thus, one or more regions of the substrate may be at a different temperature than other regions of the substrate which results in non-uniform temperatures and non-uniform processing of the substrate. The possibility of non-uniformity may also be extended to other substrate processing properties such as radio frequency (RF) or direct current (DC) application for plasma processes, and other functions the pedestal may provide during substrate processing.

Therefore, there is a need in the art for a substrate support system capable of minimizing non-uniformities in substrate processing properties in the manufacture of integrated circuits.

### SUMMARY

The present disclosure generally relates to a method and apparatus for a substrate support system utilized in a substrate process chamber. In one embodiment, a process chamber is provided. The chamber includes a chamber body enclosing a processing region, a primary substrate support and a secondary substrate support at least partially disposed in the processing region, the secondary substrate support circumscribing the primary substrate support, wherein one or both of the primary substrate support and the secondary substrate support are movable relative to each other, and the primary substrate support is rotatable relative to the secondary substrate support.

In another embodiment, a substrate process chamber is provided. The chamber includes a chamber body enclosing a processing region, a pedestal disposed in the processing region for supporting a major surface of a substrate, and an edge support member disposed in the processing region for intermittently supporting an edge of the substrate when the major surface of the substrate is not supported by the pedestal, wherein the pedestal is rotatable relative to the edge support member.

In another embodiment, a method for compensating for non-uniformities of substrate processing properties during a substrate manufacturing process is provided. The method includes transferring a substrate to a pedestal disposed in a processing chamber, positioning the substrate at a first position on a support surface of the pedestal, processing the substrate while monitoring a substrate processing property on the substrate, and re-positioning the substrate on the support surface to a second position that is different than the first position when the substrate processing property is outside a desired value.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a side cross-sectional view of a process chamber having one embodiment of a substrate support system disposed therein.

FIG. 2 is a side cross-sectional view of a process chamber having another embodiment of a substrate support system disposed therein.

FIG. 3 is a plan view of the pedestal of FIG. 2.

FIG. 4 is a cross-sectional view of a portion of a pedestal showing another embodiment of a secondary substrate support.

FIG. 5 is a flow chart showing a method utilizing the substrate support system as described herein.

To facilitate understanding, identical reference numerals have been used, wherever possible, to designate identical elements that are common to the figures. It is also contemplated that elements disclosed in one embodiment may be beneficially utilized on other embodiments without specific recitation.

### DETAILED DESCRIPTION

Embodiments described herein relate to a substrate support system and associated method for compensating for differences in temperature, electrical bias, electromagnetic energy distribution, or other non-uniformity which may affect uniform processing results on a substrate supported by a pedestal in a process chamber. The temperature, electrical bias, electromagnetic energy distribution, or other non-uniform phenomena that may affect uniform processing results on the substrate supported by the pedestal during processing are collectively referred to as substrate processing properties Correction of non-uniform substrate processing properties provide process control parameters on the substrate during processing. The non-uniformities may be detected by monitoring of the substrate during processing, observation of the azimuthal uniformity of a processed substrate, and combinations thereof. The inventive system and method may provide reduction of non-uniformities within one or more of these substrate processing properties, which provides more efficient process control during formation of structures on the substrate.

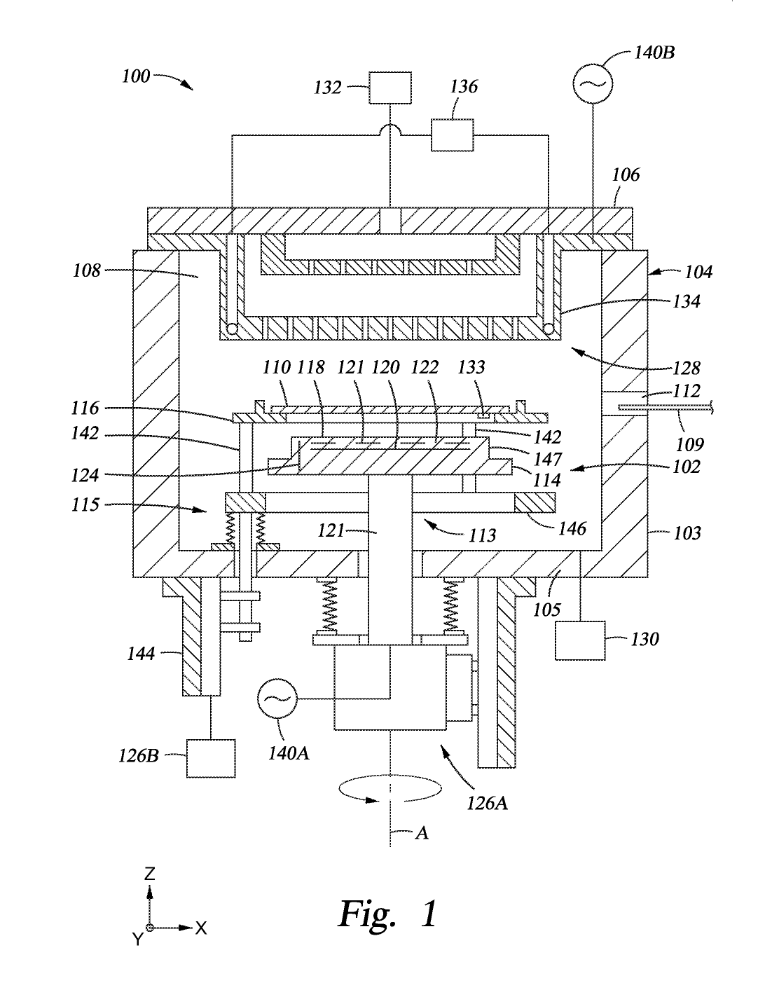

FIG. 1 is a side cross-sectional view of a process chamber 100 having one embodiment of a substrate support system 102 disposed therein. The process chamber 100 includes a chamber body 104 consisting of a sidewall 103, a bottom 105 and a lid assembly 106 that encloses a process volume 108. The substrate support system 102 is at least partially disposed in the process volume 108 and supports a substrate 110 that has been transferred to the process volume 108 through a port 112 formed in the chamber body 104.

The substrate support system 102 includes a primary substrate support 113, such as a pedestal 114, and a secondary substrate support 115, such as an edge supporting member 116. The secondary substrate support 115 may be used to intermittently support the substrate 110 above the primary substrate support 113. For example, the substrate 110 is shown on the edge supporting member 116 in a spaced apart from the pedestal 114 in FIG. 1. The substrate 110 would be in proximity to, or in contact with, the pedestal 114 during processing. For example, the pedestal 114 includes a support surface 118 that is adapted to contact (or be in proximity to) a major surface of the substrate 110 during processing. Thus, the pedestal 114 serves as a primary supporting structure for the substrate 110 in the process chamber 100.

At least one of the pedestal 114 and the edge supporting member 116 is movable relative to the other. In the processing position, the edge supporting member 116 would be in proximity to the pedestal 114 and may circumscribe (i.e., surround) the pedestal 114 such that a lower surface of the substrate 110 would be supported by the pedestal 114. In one embodiment, the pedestal 114 may be capable of movement relative to the edge supporting member 116. In one example, the edge supporting member 116 may be fixed at least in the X-Z (horizontal) plane, as well as rotationally, and the pedestal 114 is coupled to an actuator 126A via a shaft 121 that provides one or a combination of vertical movement (in the Z direction), rotational movement (about axis A), and may also provide angular movement (relative to axis A). Vertical movement may be provided by the actuator 126A to allow the substrate 110 to be transferred from the edge supporting member 116 to the support surface 118. In another embodiment, the edge supporting member 116 may be coupled to an actuator 126B via one or more support members (described in more detail below) that provides at least vertical movement (Z direction) of the edge supporting member 116. Thus, the edge supporting member 116 may move relative to the pedestal 114. Vertical movement may be provided by the actuator 1268 to allow the edge supporting member 116 to be lowered and transfer the substrate 110 to the support surface 118. In another embodiment, a combination of movement provided by the actuators 126A and 1268 may be provided to facilitate transfer of the substrate 110 between the support surface 118 and the edge supporting member 116.

The process chamber 100 may be a deposition chamber, an etch chamber, an ion implant chamber, a plasma treatment chamber, or a thermal process chamber, among others. In the embodiment shown, the process chamber is a deposition chamber and includes a showerhead assembly 128. The process volume 108 may be in selective fluid communication with a vacuum system 130 to control pressures therein. The showerhead assembly 128 may be coupled to a process gas source 132 to provide process gases to the process volume 108 for depositing materials onto the substrate 110. The showerhead assembly 128 may also include a temperature control element 134 for controlling the temperature of the showerhead assembly 128. The temperature control element 134 may be a fluid channel that is in fluid communication with a coolant source 136.

The edge supporting member 116 functions as a temporary substrate support member. The edge supporting member 116 is utilized for supporting the substrate 110 in a spaced-apart relation to the support surface 118 of the pedestal 114 as necessary (as shown in FIG. 1), which may facilitate repositioning of the substrate 110 relative to the support surface 118 of the pedestal 114 when desired. The edge supporting member 116 may include recesses or slots 133 formed therein that are sized to receive a robot blade 109 to facilitate robotic substrate transfer into and out of the process volume 108.

The pedestal 114 may include at least one embedded temperature control element 120 disposed within a pedestal body 122. In one embodiment, the embedded temperature control element 120 may be a heating or cooling element or channel, utilized to apply thermal energy to the pedestal body 122 that is absorbed by the substrate 110. Other elements may be disposed on or embedded within the pedestal body 122, such as one or more electrodes and/or vacuum ports. The temperature of the substrate 110 may be monitored by one or more sensors 124. The embedded temperature control element 120 may be zone controlled such that temperature at different areas of the pedestal body 122 may be individually heated or cooled. However, due to extenuating factors, such as imperfections in the pedestal 114 and/or non-uniformities in the substrate 110, the embedded temperature control element 120 may not be able to apply thermal energy uniformly across the entire support surface 118 and/or the substrate 110. These extenuating factors create non-uniform temperature of the substrate 110 which results in non-uniform processing of the substrate.

To counter the thermal non-uniformity that may be present on the surface of the substrate 110 (which may be determined by monitoring temperature of the substrate 110), the substrate 110 may be repositioned relative to the support surface 118. The hot or cold spots present on the surface of the substrate 110 are indicative of hot or cold spots in or on the support surface 118 of the pedestal body 122. In one example, the substrate is transferred from the support surface 118 to the edge supporting member 116 by one or a combination of movement provided by the actuators 126A and 126B. The edge supporting member 116 temporarily supports the substrate 110 in a spaced-apart relation above the pedestal 114 as shown, which allows rotation of the pedestal 114 relative to the substrate 110. This movement may be utilized to relocate hot or cold spots present in or on the support surface 118 of the pedestal body 122 (as determined by monitoring the temperature of the substrate 110). The pedestal 114 may be rotated in an angular displacement that is less than about 360 degrees, for example less than about 180 degrees, such as between about 1 degree to less than about 180 degrees, or increments therebetween. After relocation of the hot or cold spots in or on the support surface 118 of the pedestal body 122 by rotating the pedestal 114, the substrate 110 may be replaced onto the support surface 118 of the pedestal 114 by one or a combination of movement provided by the actuators 126A and 1268. Once replacement of the substrate 110 is completed, cold spots on the substrate 110 may be positioned closer to hot spots on the support surface 118 of the pedestal 114, and vice versa. Thus, any localized non-uniform temperature distribution on the surface of the substrate 110 is averaged providing a substantial even temperature distribution across the entire substrate (i.e., +/− a few degrees Celsius).

In another embodiment, the pedestal 114 may be an electrostatic chuck and the pedestal 114 may include one or more electrodes 121. For example, the pedestal 114 may be coupled to a power element 140 that may be a voltage source providing power to the one or more electrodes 121. The voltage source may be a radio frequency (RF) controller or a direct current (DC) controller. In another example, the pedestal 114 may be made of a conductive material and function as a ground path for RF power from a power element 1408 distributed by the showerhead assembly 128. Thus, the process chamber 100 may perform a deposition or etch process utilizing RF or DC plasmas. As these types of plasmas may not be perfectly concentric or symmetrical, RF or DC hot spots (i.e., electromagnetic hot spots) may be present on the substrate 110. These electromagnetic hot spots may create non-uniform deposition or non-uniform etch rates on the surface of the substrate 110.

To counter the electromagnetic hot spots that may be present on the surface of the substrate 110 (which may be determined by observing the plasma sheath), the substrate 110 may be repositioned relative to the support surface 118 using the edge supporting member 116 according to the process described above. For example, a non-uniform plasma sheath may indicate non-uniform energy distribution in the plasma. The repositioning of the substrate 110 is utilized to redistribute any electromagnetic hot spots, and any localized non-uniform energy distribution on the surface of the substrate 110 is averaged thus providing an equilibrated energy distribution across the substrate.

During processing in a deposition or etch process, the pedestal 114 is typically rotated. However, any anomalies in temperature distribution, electrical bias or electromagnetic energy distribution determined to be present on the substrate 110 are fixed as the position of the substrate 110 is fixed relative to the support surface 118. However, movement of the substrate 110 relative to the support surface 118 compensates for these differences in temperature, electrical bias, electromagnetic energy distribution by averaging these differences which results in substantially uniform temperature distribution, electrical bias or electromagnetic energy distribution on the substrate 110.

In one embodiment, in addition to the pedestal 114, the substrate support system 102 includes the edge supporting member 116 that is supported by one or more pins 142. At least one of the one or more pins 142 may be coupled directly to a linear drive 144 or coupled to a lift ring 146 as shown. Further, the edge supporting member 116 may be a deposition ring providing a shielding function when not used to support the substrate 110. For example, when the substrate 110 is supported by the support surface 118 of the pedestal 114, and the edge supporting member 116 at least partially surrounds the pedestal 114, the edge supporting member 116 may shield chamber components from deposition or etch by-products. In one embodiment, the edge supporting member 116 may remain in partial contact with the substrate 110 during processing of the substrate 110. In one aspect, the edge supporting member 116 may be utilized to support the perimeter of the substrate 110 during processing (when the pedestal 114 is not rotated during processing). In another aspect, the edge supporting member 116 may be made of a conductive material that may be used to provide an electrical bias to the substrate 110 in a plating process, for example. While the edge supporting member 116 is shown coupled to the actuator 126B providing movement thereof relative to the pedestal 114, the edge supporting member 116 may simply rest on an upper surface of the pins 142. In this embodiment, the pedestal 114 may move relative to the edge supporting member 116 allowing the substrate 110 to be transferred to the support surface 118. Continuing movement of the pedestal 114 in the Z direction would then allow the edge supporting member 116 to be supported by a peripheral shoulder region 147 formed in the pedestal 114. As the edge supporting member 116 is raised above the height of the pins 142 allowing rotational movement of the pedestal 114, the substrate 110 and the edge supporting member 116.

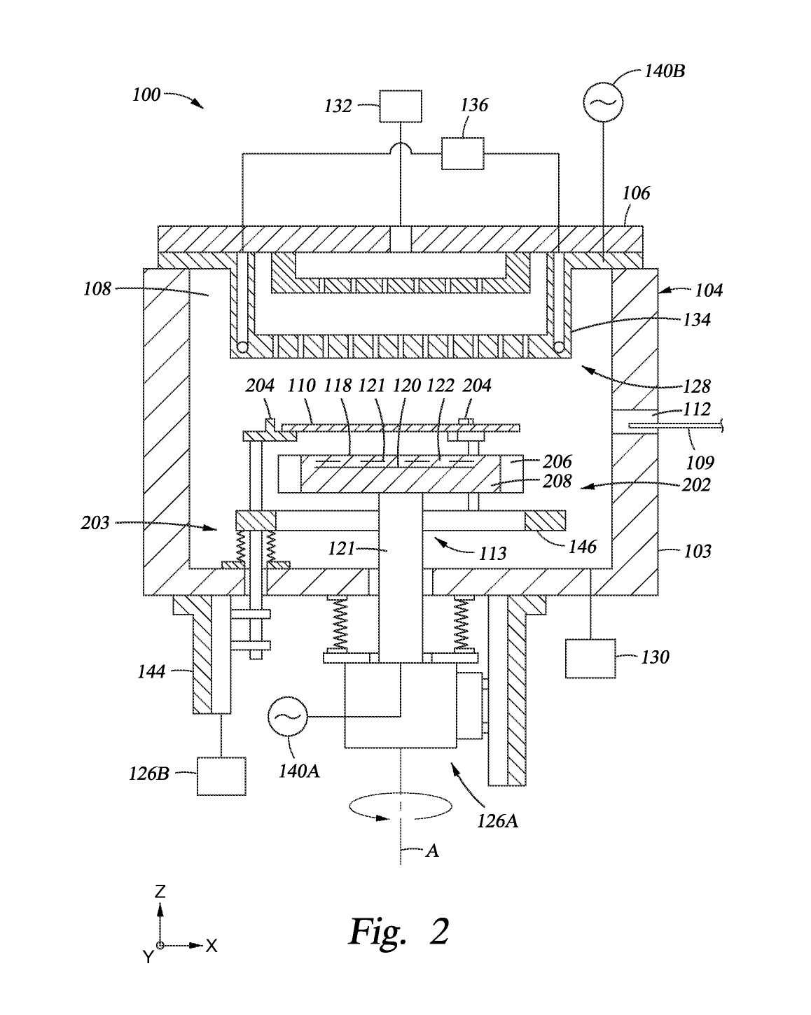

FIG. 2 is a side cross-sectional view of a process chamber 100 having another embodiment of a substrate support system 202 disposed therein. As in the embodiments described in FIG. 1, the substrate support system 202 includes a pedestal 114 and the actuator 126A as well as the associated lift and sealing members. However, in this embodiment, a secondary substrate support 203 of the substrate support system 202 includes a plurality of edge support members 204 in place of the edge supporting member 116 shown in FIG. 1. The edge support members 204 may be discrete fingers that selectively support the edge of the substrate 110 when in use. In this embodiment, the pedestal 114 includes a cutout region 206 corresponding to each of the edge support members 204. Each cutout region 206 allows the respective edge support members 204 to clear a bottom surface 208 of the pedestal 114 to allow free rotation of the pedestal 114 when the substrate 110 is supported on the support surface 118 thereof. Lifting and lowering of the edge support members 204 may be accomplished by the actuator 126B, the lift ring 146, and associated pins 142.

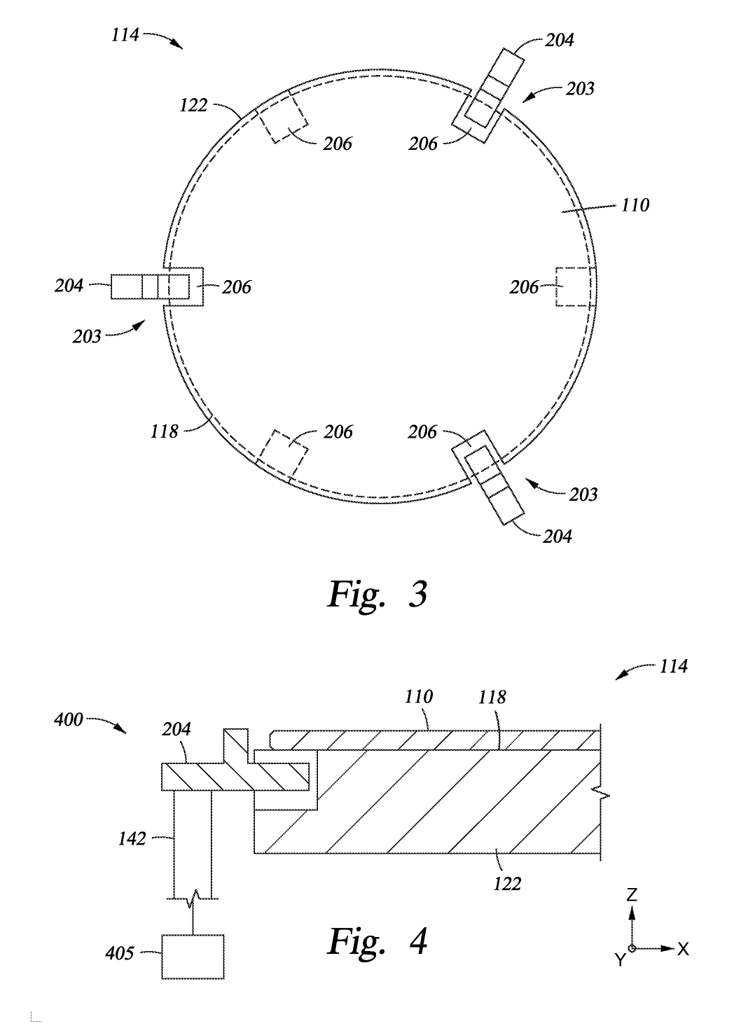

FIG. 3 is a plan view of the pedestal 114 of FIG. 2. Three edge support members 204 are shown in respective cutout regions 206. Each of the cutout regions 206 of the pedestal 114 may be aligned with each of the edge support members 204 when the edge support members 204 are utilized to space the substrate 110 away from the support surface 118 of the pedestal 114 by use of an encoder or other rotational sensing/indexing metric coupled to the pedestal 114 and/or the actuator 216A (shown in FIG. 2). While only three edge support members 204 are shown, the secondary substrate support 203 may include at least two edge support members 204 and more than three edge support members 204. The number of edge support members 204 may coincide with a corresponding number of cutout regions 206. Optionally or additionally, additional cutout regions 206 (shown in phantom) may be added to the pedestal 114. The cutout regions 206 may be utilized as necessary to provide rotation of the pedestal 114 in 120 degree increments, 60 degree increments, 30 degree increments, as well as less than 30 degree increments, while facilitating alignment with the edge support members 204. Additional cutout regions 206 may also be added to facilitate alignment with the edge support members 204 at increments greater than 120 degrees.

FIG. 4 is a cross-sectional view of a portion of a pedestal 114 showing another embodiment of a secondary substrate support 400. In this embodiment, an edge support member 204 is coupled to a pin 142 that is coupled to an actuator 405. Similar to other embodiments, the actuator 405 is utilized to raise and lower the substrate 110 relative to the pedestal 114 in the Z direction. However, in this embodiment the actuator 405 is utilized to move the edge support member 204 laterally (in the X direction) relative to the pedestal 114. While not shown, other pins 142 and edge support members 204 may be disposed about the periphery of the pedestal 114 similar to the embodiment described in FIG. 2. In this embodiment, an actuator 405 may be necessary for each of the edge support members 204.

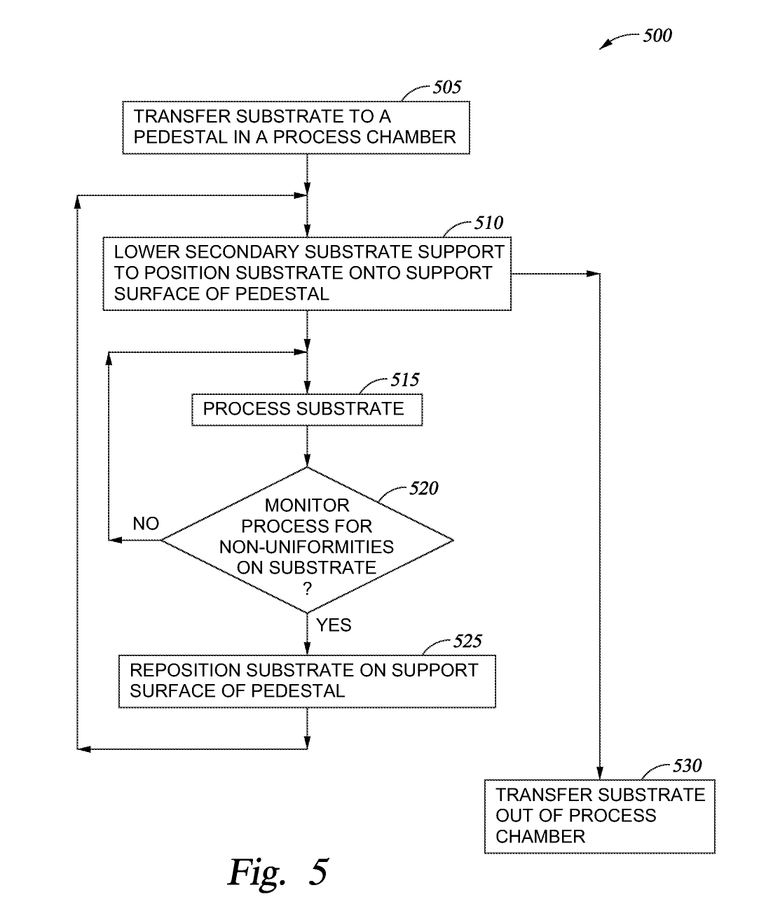

FIG. 5 is a flow chart showing a method 500 of compensating for non-uniformities of substrate processing properties during a substrate manufacturing process. The method 500 may be practiced utilizing the substrate support system 102 or 202 as described herein, or other suitable apparatus. The method 500 includes, at block 505, transferring a substrate 110 to a pedestal 114 in a process chamber 100. The method at block 505 may also include transferring the substrate 110 into the process chamber 100 on a robot blade 109 and transferring the substrate from the robot blade 109 to the secondary substrate support. In the embodiment of FIG. 1, the transfer included at block 505 also includes aligning the edge supporting member 116, particularly the slots 133, in a plane configured to receive the robot blade 109 which would extend through the transfer port 112. Once the substrate 110 is substantially concentric with the edge supporting member 116, the robot blade 109 may be retracted from the process chamber 100 through the transfer port 112. In the embodiment of FIG. 2 or 4 where the edge support members 204 are utilized, the transfer described at block 505 includes positioning the substrate 110 above the pedestal 114, substantially concentric with the pedestal 114, and above the area defined by a circumference of the edge support members 204. The actuator 126B (shown in FIG. 2) or the actuator 405 (shown in FIG. 4) may then be used to move the edge support members 204 into proximity with the edge of the substrate 110. In this embodiment, the edge support members 204 may be spaced to not interfere with the travel path of the robot blade 109. Once the edge support members 204 grip the edge of the substrate 110 the substrate 110 may be lifted off the robot blade 109 and the robot blade 109 may be retracted.

At block 510, the substrate 110 is lowered onto the support surface 118 of the pedestal 114 using either the edge supporting member 116 of FIG. 1 or the edge support members 204 of FIGS. 2 and 4. The substrate 110 may be positioned in a first position on the support surface 118 of the pedestal 114. In the embodiment of FIG. 1, the edge supporting member 116 may be lowered until the support surface 118 of the pedestal 114 is at least partially supporting the substrate 110 and may be further lowered to be proximate the peripheral shoulder region 147. In the embodiment of FIG. 2, the edge support members 204 may be lowered until the support surface 118 of the pedestal 114 is at least partially supporting the substrate 110 and may be further lowered to clear the bottom surface 208 of the pedestal 114. In the embodiment of FIG. 4, the edge support members 204 may be actuated in the X direction to clear the sidewall of the pedestal 114. In any of these embodiments, a major surface (e.g., the bottom or backside) of the substrate 110 is supported by the support surface 118 of the pedestal 114 and the substrate 110 may be processed.

At block 515, as the major surface of the substrate 110 is supported by the pedestal 114, the pedestal 114, and the substrate 110 supported thereon, may be rotated, raised, lowered, and combinations thereof, in order to process the substrate 110. For example, deposition or etch processes using gases or plasmas thereof that may be generated in the process chamber 100 as the substrate 110 is supported on the pedestal 114. Processing of the substrate 110 may include raising or lowering the pedestal 114 relative to the showerhead assembly 128. Processing of the substrate 110 may also include rotation of the pedestal 114.

At block 520, the process performed on the substrate 110 is monitored. Metrics such as substrate temperature, electrical bias and/or electromagnetic energy distribution (i.e., substrate processing properties) may be monitored across the surface of the substrate 110 to determine any non-uniformities thereof that are determined to be outside of desired parameters or a target value. The desired parameters or target value may include substrate temperature, electrical bias and/or electromagnetic energy distribution on the substrate 110 being within a narrow range (i.e., window) of process parameters. With respect to temperature, the desired parameter or target value may include a temperature that varies within a few degrees Celsius. If the metrics indicate uniform conditions (i.e., within desired parameters or a target value) the processing of the substrate 110 may continue. If non-uniformities (i.e., metrics outside of desired parameters or a target value) are present, the method progresses to block 525 which includes repositioning the substrate 110 on the support surface 118 of the pedestal 114.

The in-situ process described at block 520 may be optional. Monitoring of processed substrates may be used with the method 500 to determine the presence of non-uniformities. This ex-situ monitoring may be utilized to determine positioning parameters for processing subsequent substrates using a specific recipe. For example, ex-situ monitoring may be utilized to determine the angle of rotation of the pedestal 114, the amount (i.e., number) of repositioning(s) of the substrate 110 on the pedestal 114, the timing of repositioning(s) of the substrate 110 on the pedestal 114, and combinations thereof. Thus, once the non-uniformities are determined, either by the in-situ process described at block 520 and/or the ex-situ monitoring, the monitoring may be suspended for a particular manufacturing scheme.

At block 525, in the embodiment of FIG. 1, the edge supporting member 116 of FIG. 1 is used to support the substrate 110 while the substrate 110 is spaced away from the support surface 118 of the pedestal 114. In this spaced-apart relation the pedestal 114 may be rotated at some increment less than about 360 degrees. In the embodiment of FIGS. 2 and 4, the edge support members 204 are used to support the substrate 110 and move the substrate 110 away from the support surface 118 of the pedestal 114 allowing the pedestal 114 to rotate at some increment less than about 360 degrees. After the rotation of the pedestal 114, the substrate 110 may be again placed onto the support surface 118 of the pedestal 114 as described at block 510. Processing as described at block 515 may continue. During processing, the process may be monitored as described at block 520 and block 525, followed by block 515, may be repeated as necessary until processing is completed. When processing is completed, the substrate 110 may then be transferred out of the process chamber 100 by spacing the substrate 110 from the support surface 118 of the pedestal 114 as described at block 525, and a process of transferring the substrate 110 from the edge supporting member 116 (FIG. 1) or the edge support members 204 (FIGS. 2 and 4) to the robot blade 109. The transfer of the substrate 110 to the robot blade 109 may be the substantial reverse of the process described at block 505.

Embodiments of the substrate support system 102 or 202 enable an in-situ (intra-chamber) process for compensating for non-uniformities in substrate processing properties. The inventive substrate support system 102 or 202 as described herein may reduce costs and increase throughput as the substrate processing properties may be compensated without removal of the substrate from the process chamber and/or breaking of vacuum in order to use a robot blade (or other peripheral substrate support mechanism) to temporarily support the substrate. Additionally, device quality and/or device yield may be enhanced since the non-uniformities in substrate processing properties are minimized or eliminated, which provides uniform deposition on all portions of the substrate.

While the foregoing is directed to embodiments of the present disclosure, other and further embodiments of the disclosure may be devised without departing from the basic scope thereof, and the scope thereof is determined by the claims that follow.

1. A substrate process chamber, comprising:
a chamber body enclosing a processing region;
a primary substrate support and a secondary substrate support at least partially disposed in the processing region, the secondary substrate support circumscribing the primary substrate support, wherein one or both of the primary substrate support and the secondary substrate support are linearly movable relative to each other, and the primary substrate support is rotatable relative to the secondary substrate support.

2. The process chamber of claim 1, wherein the primary substrate support comprises:
a pedestal; and
an actuator operable to rotate the pedestal.

3. The process chamber of claim 2, wherein the secondary substrate support comprises:
a single edge support member for supporting an edge of a substrate.

4. The process chamber of claim 3, wherein the single edge support member includes one or more slots to receive a portion of a robot blade.

5. The process chamber of claim 2, wherein the pedestal comprises a peripheral shoulder region to at least partially receive the secondary substrate support.

6. The process chamber of claim 3, further comprising:
an actuator operable to vertically move the single edge support member.

7. The process chamber of claim 2, wherein the secondary substrate support comprises:
a plurality of edge support members for supporting an edge of a substrate.

8. The process chamber of claim 7, further comprising:
an actuator operable to vertically move the plurality of edge support members.

9. The process chamber of claim 7, further comprising:
an actuator operable to move the plurality of edge support members vertically or laterally.

10. The process chamber of claim 7, wherein the pedestal comprises:
a peripheral edge having a plurality of cutout regions to at least partially receive a respective edge support member of the plurality of edge support members.

11. A substrate process chamber, comprising:
a chamber body enclosing a processing region;
a pedestal disposed in the processing region for supporting a major surface of a substrate; and
an edge support member disposed in the processing region for intermittently supporting an edge of the substrate when the major surface of the substrate is not supported by the pedestal, wherein the pedestal is rotatable relative to the edge support member.

12. The process chamber of claim 11, wherein the edge support member comprises a ring.

13. The process chamber of claim 12, wherein the ring includes one or more slots to receive a portion of a robot blade.

14. The process chamber of claim 12, further comprising an actuator operable to move the ring vertically.

15. The process chamber of claim 14, wherein the pedestal comprises:
a peripheral shoulder region to at least partially receive the ring.

16. The process chamber of claim 11, wherein the edge support member comprises:
a plurality of edge support members.

17. The process chamber of claim 16, further comprising:
an actuator operable to vertically move the plurality of edge support members.

18. The process chamber of claim 16, further comprising:
an actuator operable to move the plurality of edge support members vertically or laterally.

19. The process chamber of claim 16, wherein the pedestal comprises:
a peripheral edge having a plurality of cutout regions to at least partially receive a respective edge support member of the plurality of edge support members.

20. A method for compensating for non-uniformities of substrate processing properties during a substrate manufacturing process, the method comprising:
positioning a substrate in a first position on a support surface of a pedestal disposed in a processing chamber;
processing the substrate while in the first position;
re-positioning the substrate to a second position on the support surface that is different than the first position; and
processing the substrate in the second position.
